(19) United States
(12) Patent Application Publication
(10) Pub. No.: US 2015/0008488 A1
(43) Pub. Date: Jan. 8, 2015

(54) UNIFORM HEIGHT REPLACEMENT METAL GATE

(71) Applicants: STMICROELECTRONICS, INC., Coppell, TX (US); INTERNATIONAL BUSINESS MACHINES CORPORATION, Armonk, NY (US)

(72) Inventors: LINDSEY HALL, PLEASANT VALLEY, NY (US); VIRAJ Y. SARDESAI, POUGHKEEPSIE, NY (US); CUNG D. TRAN, NEWBURGH, NY (US)

(21) Appl. No.: 13/933,203

(22) Filed: Jul. 2, 2013

(51) Int. Cl. H01L 29/66; H01L 29/78

(52) U.S. Cl. CPC H01L 29/66636; H01L 29/78
USPC 257/288; 438/300

(57) ABSTRACT

A method of manufacturing a semiconductor structure includes forming a raised source-drain region in a semiconductor substrate adjacent to a dummy gate and forming a chemical mechanical polish (CMP) stop layer over the gate structure and above a top surface of the semiconductor substrate. A first ILD layer is formed above the CMP stop layer. The first ILD layer is removed to a portion of the CMP stop layer located above the gate structure and a portion of the CMP stop layer located above the gate structure is also removed to expose the dummy gate. The dummy gate is replaced with a metal gate and the metal gate is polished until the CMP stop layer located above the raised source-drain region is reached.

### BACKGROUND

### Field of the Invention

The present invention generally relates to semiconductor devices, and more particularly to field effect transistor devices including replacement metal gate structures, and a method for making the same.

Complementary Metal-oxide-semiconductor (CMOS) technology is commonly used for fabricating field effect transistors (FETs) as part of advanced integrated circuits (IC), such as CPUs, memory, storage devices, and the like. At the core of planar FETs, a channel region is formed in an n-doped or p-doped semiconductor substrate on which a gate structure is formed. The overall fabrication process is well known in the art, and includes forming a gate structure over a channel region connecting a source region and a drain region within the substrate on opposite ends of the gate, typically with some vertical overlap between the gate and the source-drain region.

Scaling down of transistor dimensions requires a high-k metal gate to reduce gate leakage and improve device performance. A polycristalline silicon material, commonly referred as polysilicon or poly, is normally used in the gate manufacturing process. Polysilicon exhibits high thermal resistivity, which makes a polysilicon gate resistant to high temperature processes such as high temperature annealing. The replacement of a polysilicon gate with a metal gate electrode is frequently used in CMOS fabrication to address problems related to high temperature processing on metal materials. This process is known as replacement metal gate (RMG) or gate last process. A RMG process includes the formation of a dummy polysilicon gate structure, commonly referred to as a dummy poly gate or simply a dummy gate, in the semiconductor substrate. The device manufacturing may continue until deposition of an interlayer dielectric (ILD) layer. After the ILD layer deposition, the dummy gate may be removed and replaced with a high-k metal gate.

Known RMG technology usually involves additional processes, such as chemical mechanical polishing (CMP) of the ILD layer that may result in non-uniform gate height, in turn affecting device performance. For instance, poor control of combined poly open and replacement metal (aluminum or other) CMP during the RMG process results in shorter gate height.

### SUMMARY

A method for RMG process that allows precise control of gate height within the semiconductor device and in turn, of the corresponding RMG contact with source-drain regions is desirable.

According to an embodiment of the present invention, a method of manufacturing a semiconductor structure includes: forming a chemical mechanical polish (CMP) stop layer above a dummy gate and above a top surface of a semiconductor substrate. A first ILD layer is formed and then removed until the CMP stop layer located above the gate structure is reached.

The method further includes: forming a raised source drain region in a semiconductor substrate adjacent to a dummy gate and forming a chemical mechanical polish (CMP) stop layer over the gate structure and above a top surface of the semiconductor substrate. A first ILD layer is formed above the CMP stop layer. The first ILD layer is removed to a portion of the CMP stop layer located above the gate structure and the portion of the CMP stop layer located above the gate structure is removed to expose the dummy gate. The method further includes: replacing the dummy gate with a metal gate and polishing the metal gate until a top portion of the CMP stop layer located above the raised source-drain region is reached. In a related aspect of the invention, a second ILD layer is formed above the structure and contacts are formed within the second ILD layer, the contacts extending from a top surface of the second ILD layer to the raised source-drain region.

According to another embodiment of the present invention, a semiconductor device includes: a metal gate structure located on a top surface of a semiconductor substrate between a raised source-drain region, a CMP stop layer located on top of the raised source-drain region and above the top surface of the semiconductor substrate and a portion of an interlayer dielectric (ILD) layer positioned on a top of the CMP stop layer and between a substrate contact and a gate contact. The device further includes: two or more gate structures where a height of one metal gate structure is substantially similar to the height of another metal gate structure.

### BRIEF DESCRIPTION OF THE SEVERAL VIEWS OF THE DRAWINGS

The features and advantages of the present disclosure will become apparent from the following detailed description of illustrative embodiments thereof, which is to be read in connection with the accompanying drawings. The various features of the drawings are not to scale as the illustrations are for clarity in facilitating one skilled in the art in understanding the disclosure in conjunction with the detailed description. In the drawings:

FIG. 1 is a cross sectional view of a semiconductor structure depicting a dummy poly gate layer and source-drain recesses formed onto a semiconductor substrate according to one embodiment of the present disclosure;

FIG. 2 is a cross sectional view of a semiconductor structure depicting the formation of an embedded epitaxial doped material in the source-drain recesses shown in FIG. 1 to form the device raised source-drain regions according to one embodiment of the present disclosure;

FIG. 3 is a cross sectional view of a semiconductor structure depicting the deposition process of a CMP stop layer on top of the dummy gates and raised source-drain regions shown in FIG. 2 according to one embodiment of the present disclosure;

FIG. 4 is a cross sectional view of a semiconductor structure depicting the deposition process of an ILD layer on top of the CMP stop layer shown in FIG. 3 according to one embodiment of the present disclosure;

FIG. 5 is a cross sectional view of a semiconductor structure depicting the CMP of the ILD layer shown in FIG. 4 according to one embodiment of the present disclosure;

FIG. 6 is a cross sectional view of a semiconductor structure depicting a top part of the CMP stop layer being etched from the top of the dummy gate shown in FIG. 5 allowing the removal of the hard mask layer according to one embodiment of the present disclosure;

FIG. 7 is a cross sectional view of a semiconductor structure depicting the replacement of the dummy gate shown in FIG. 6 with a metal gate according to one embodiment of the present disclosure;

FIG. 8 is a cross sectional view of a semiconductor structure depicting the metal gate shown in FIG. 7 being polished to the top of the CMP stop layer according to one embodiment of the present disclosure; and

FIG. 9 is a cross sectional view of a semiconductor structure depicting the formation of substrate contacts according to one embodiment of the present disclosure.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Exemplary embodiments now will be described more fully herein with reference to the accompanying drawings, in which exemplary embodiments are shown. This invention may, however, be modified in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessary obscuring the presented embodiments.

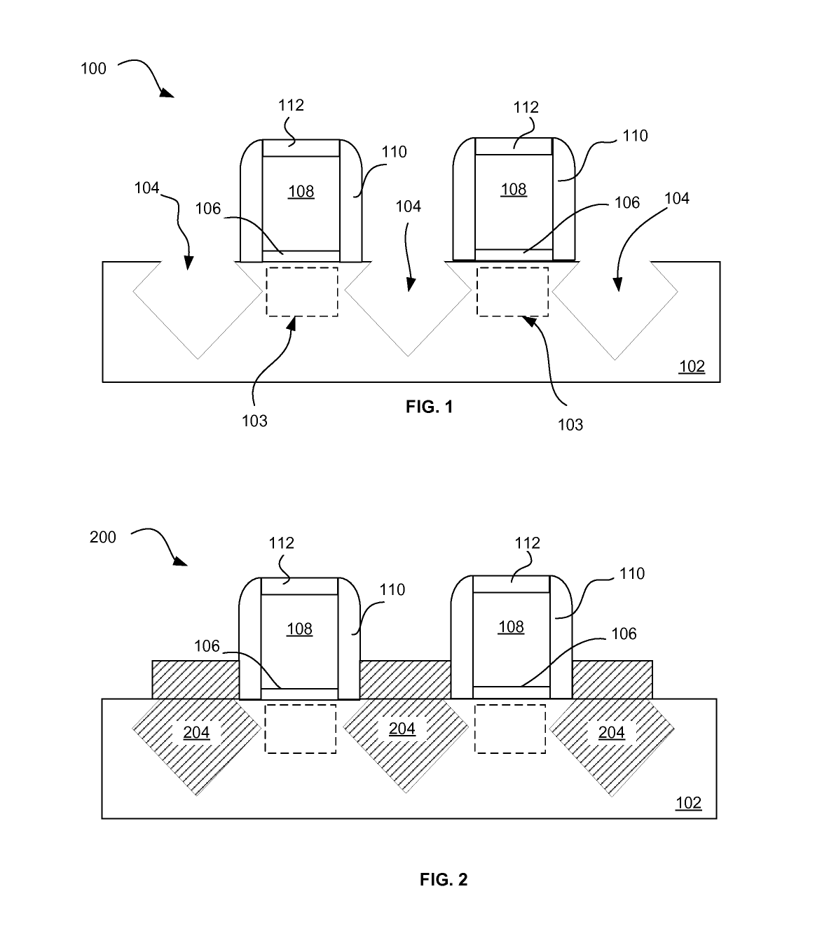

One method of manufacturing a semiconductor structure is described in detail below by referring to the accompanying drawings in FIGS. 1-9, in accordance with some illustrative embodiments of the present invention.

Referring to FIG. 1, according to an embodiment of the present disclosure, a semiconductor structure 100 may include a semiconductor substrate 102. The semiconductor substrate 102 may be made of any semiconductor material including, but not limited to: silicon, germanium, silicon-germanium alloy, carbon-doped silicon, carbon-doped silicon-germanium alloy, and compound semiconductor materials. The semiconductor substrate 102 may further include isolation regions (not shown), for instance, shallow trench isolation (STI) regions. Such isolation regions may separate active regions within the semiconductor substrate 102. The isolation regions may be formed by etching the semiconductor substrate 102 to create recesses that may later be filled with an insulator material using any deposition method known in the art. The isolation regions may consist of any low-k dielectric material including, but not limited to: silicon nitride, silicon oxide, silicon oxy-nitride and fluoride-doped silicate glass.

The semiconductor structure 100 may further include a plurality of n-channel field effect transistor (n-FET) devices and p-channel field effect transistor (p-FET) devices. The n-FET and p-FET devices may have a gate dielectric 106 which may be formed over the semiconductor substrate 102 by any deposition method known in the art, for example, by chemical vapor deposition (CVD), plasma-enhanced chemical vapor deposition (PECVD), high-density CVD (HDCVD), physical vapor deposition (PVD), plating, sputtering, evaporation, and chemical solution deposition of a dielectric material. Gate dielectric 106 may be formed through oxidizing a top surface of substrate 102 as well. In one embodiment, the gate dielectric 106 may include a high-k dielectric material having a dielectric constant greater than, for example, 3.9, which is the dielectric constant of silicon oxide.

The devices formed as discussed below, such as the structure 100, may be an n-FET or p-FET device by doping the substrate as is known in the art. The devices discussed below are generically referred to as FET devices.

The semiconductor structure 100 may further include a dummy gate 108. The dummy gate 108 may be formed using conventional techniques known in the art. For example, the dummy gate 108 may be formed by depositing a blanket layer of polysilicon. In some embodiments, multiple gates may be formed above a single channel region when fabricating multiple transistor structures having shared source-drains regions (not shown).

The semiconductor structure 100 may further include a hard mask layer 112 located above the dummy gate 108. The hard mask layer 112 may be formed by any deposition method known in the art including, for example, by CVD, PECVD, HDCVD, PVD, plating, sputtering, evaporation, and chemical solution deposition. The hard mask layer 112 may be made of any known semiconductor material including, but not limited to: silicon nitride, silicon oxy-nitride and silicon carbide.

The dummy gate 108 may further include one or more dielectric spacers, for example spacers 110. The spacers 110 may be formed by depositing or growing a conformal dielectric layer, followed by an anisotropic etch that removes the dielectric from the horizontal surfaces of the semiconductor structure 100, while leaving it on the sidewalls of the dummy gate 108. In a RMG process flow the spacers 110 may remain on the sidewalls of a dummy gate 108. In one embodiment, the spacers 110 may include any suitable dielectric material such as silicon nitride. In one embodiment, the spacers 110 may have a horizontal width, or thickness, ranging from about 3 nm to about 30 nm. The spacers 110 may include a single layer; however, the spacers 110 may include multiple layers of dielectric material. The spacers 110 may be positioned along the sidewalls of the dummy gate 108 and separate a subsequently formed metal gate from an epitaxial embedded source-drain region, as shown in FIG. 7 and discussed in more detail below.

In one embodiment of the present disclosure, source-drain recesses 104 may be formed adjacent to a channel region 103 in the semiconductor substrate 102. The source-drain recesses may be formed by etching the semiconductor substrate 102 using a dry etching technique. Initial source-drain recesses in the semiconductor substrate 102 may have a U shape (not shown), which may then be processed into the present sigma shape shown in FIG. 1. The sigma-shaped source-drain recesses 104 as shown in the semiconductor structure 100 of FIG. 1 may be made utilizing conventional techniques well known to those skilled in the art; for example, anisotropic dry-etching followed by anisotropic wet-etching. The sigma-shaped source-drain recesses 104 may also be referred to as diamond-shaped recesses. The sigma-shaped recesses 104 may be formed to increase stress force on the channel region 103 by narrowing the space between source and drain regions.

Referring now to FIG. 2, according to one embodiment of the present disclosure, a doped material having compressive or tensile strain characteristics may be grown epitaxially within the source-drain recesses 104 (FIG. 1) including an epitaxial (or epi) overfill region extending above the semiconductor substrate 102 to form a raised source-drain (RSD) region 204 in the semiconductor device 200. In one embodiment, a mask (not shown) may be used to prevent the doped material from growing in unwanted regions of the structure 200, and limit its growth to form the raised-source drain regions 204, as shown in FIG. 2. RSD regions including the doped material may provide low parasitic resistance and apply a stress on the device for improved carrier mobility. The epitaxial doped material used to form the RSD region 204 of a p-FET device may have a large lattice constant relative to the lattice constant of the semiconductor substrate 102. The epitaxial doped material used to form the RSD region 204 of an n-FET device may have a small lattice constant relative to the lattice constant of the semiconductor substrate 102. The difference in the lattice constant between the doped material and the semiconductor substrate 102 may apply a compressive or tensile stress on the channel region 103. Lattice stress may be transferred from the raised source-drain region 204 to the underlying semiconductor substrate 102. Dopants may be included by in-situ doping of the doped material forming the RSD region 204.

For example, the epitaxial doped material used to form RSD region 204 in a p-FET device may include a silicon-germanium (SiGe) material, where the atomic concentration of germanium (Ge) may range from about 10-80%. In an embodiment of the present disclosure, the concentration of germanium (Ge) may be about 25-50%. The epitaxial doped material forming the RSD region 204 may provide a compressive stress to the channel region 103. More specifically, the epitaxial doped material forming the RSD region 204 may induce a compressive stress in the channel region 103 of the p-FET device which may enhance carrier mobility and increase drive current. Thus, the RSD region 204 may include enhanced carrier mobility provided by the epitaxial doped material. P-type dopants such as boron may be incorporated into the epitaxial doped material by in-situ doping. The percentage of boron may range from 1E¹⁹cm⁻³ to 2E²¹cm⁻³, preferably 1E²⁰cm⁻³ to 1E²¹cm⁻³.

For example, the epitaxial doped material used to form RSD region 204 in an n-FET device may include a carbon-doped silicon (Si:C) material, where the atomic concentration of carbon (C) may range from about 0.4-3.0%. The epitaxial doped material forming the RSD region 204 may provide a tensile stress to the channel region 103. More specifically, the epitaxial doped material forming the RSD region 204 may induce a tensile stress in the channel region 103 of the n-FET device which may enhance carrier mobility and increase drive current. Thus, the RSD region 204 may include enhanced carrier mobility provided by the epitaxial doped material. N-type dopants such as phosphorus or arsenic may be incorporated into the epitaxial doped material by in-situ doping. The percentage of phosphorus or arsenic may range from 1E¹⁹cm⁻³ to 2E²¹cm⁻³, preferably 1E²⁰cm⁻³ to 1E²¹cm⁻³.

In another embodiment of the present disclosure, a source-drain region may be formed in the semiconductor substrate 102 by any suitable technique known in the art. For example, the source-drain region may alternatively be formed directly in the semiconductor substrate 102 without creating a recess in the semiconductor substrate 102. The process may include ion implantation, photolithography, diffusion or any other suitable process that may allow inclusion of doping species in the semiconductor substrate 102. The doping species may vary according to p-FET or n-FET devices. One or more annealing processes may be conducted to activate the doped regions (not shown). After the activation process, raised source-drain regions may be formed above the doped source-drain regions using known techniques, such as, for example, epitaxial growth. The raised source-drain regions may be formed with a doped material as described above.

Referring now to FIG. 3, the semiconductor structure 300 depicts the formation of a CMP stop layer 302 above the dummy gate 108 and the RSD region 204. The CMP stop layer may extent along a top surface of the semiconductor substrate 102. The CMP stop layer 302 may be formed by any deposition method known in the art, for example, by CVD, PECVD, HDCVD, PVD, atomic layer deposition (ALD), plating, sputtering, evaporation, and chemical solution deposition. The CMP stop layer 302 may include a dense carbon-based film, such as silicon nitride, that may be resistant to chemical mechanical polish (CMP) processes. The CMP stop layer 302 may exhibit a relatively low etch rate causing the CMP stop layer 302 to function as an etch stop during subsequent chemical mechanical polishing techniques.

The CMP stop layer 302 may have a thickness of approximately 5-25 nm. A CMP stop layer of thickness less than 5 nm may not be able to effectively stop the polishing process causing punch through. Furthermore, a CMP stop layer 302 of thickness greater than 25 nm may affect etch selectivity depending on the selected carbon-based material forming the CMP stop layer 302. For example, a carbon nitride (SiCN) CMP stop layer including a thickness greater than 25 nm may include limited etch selectivity to gate spacers while a CMP stop layer made of conformal carbon (C) including a thickness greater than 25 nm may be easily removed but may cause problems during integration with the replacement metal gates (RMG). Additionally, a thickness greater than 25 nm may cause problems when etching the CMP stop layer through contact diffusion regions.

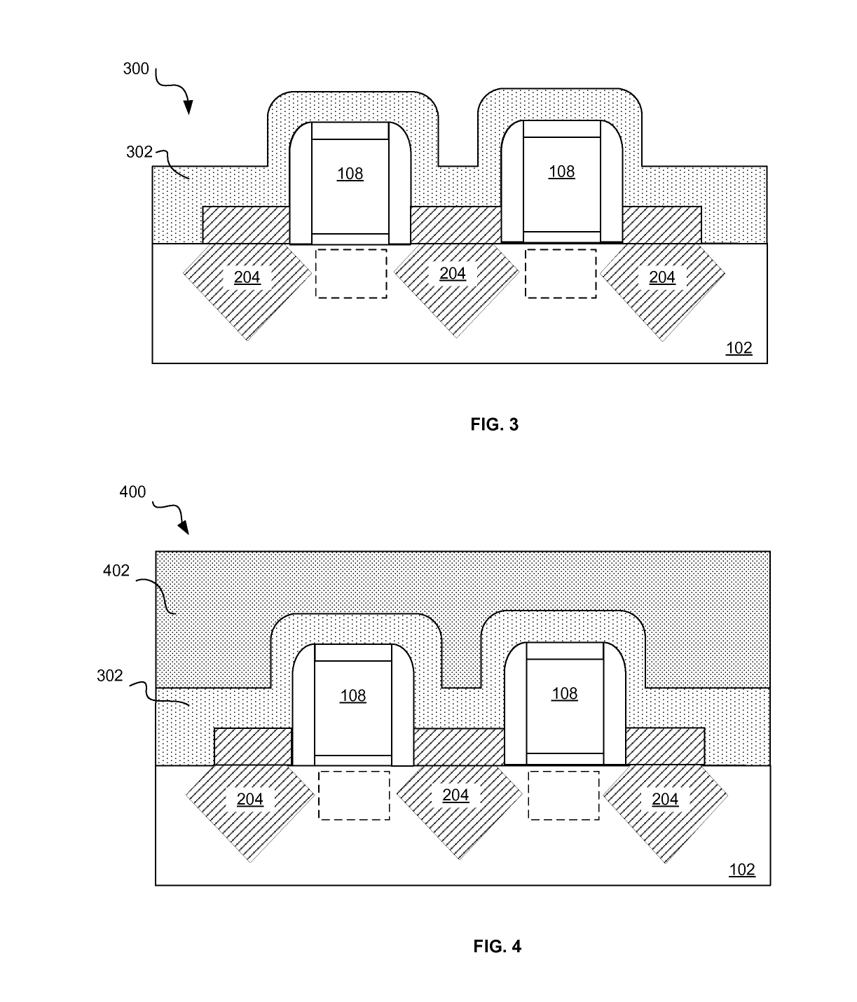

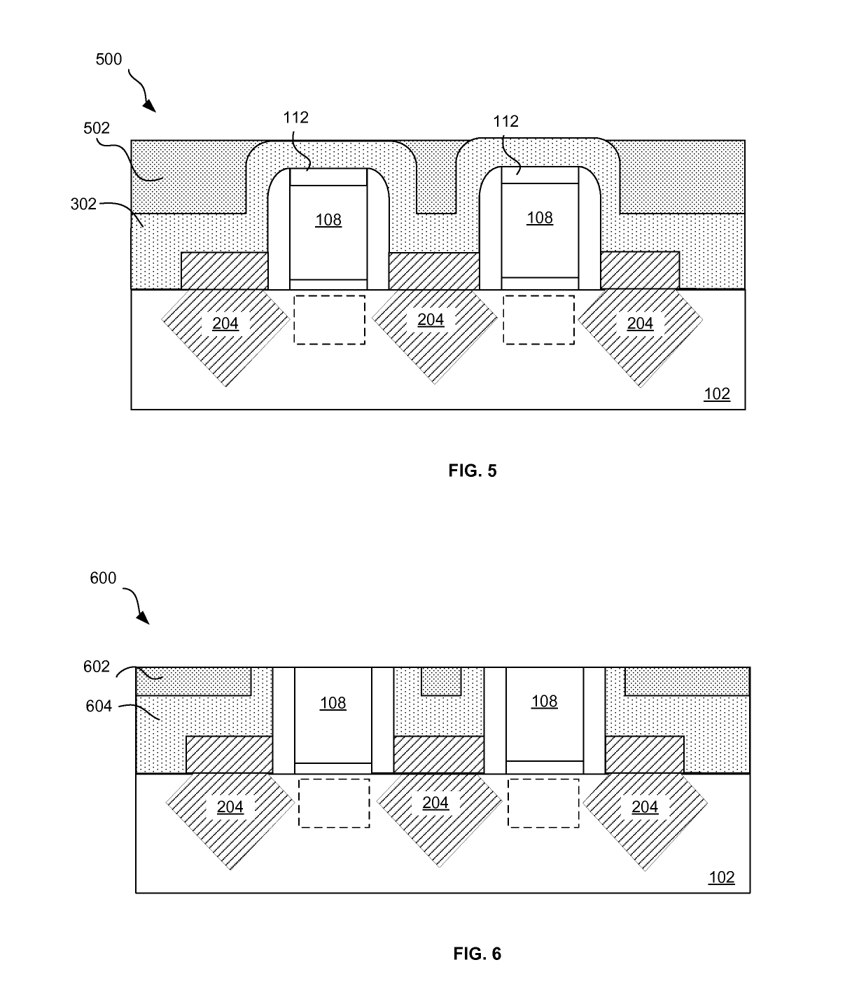

Referring now to FIG. 4, a first ILD layer 402 may be deposited above the CMP stop layer 302 by means of any suitable deposition method. The first ILD layer 402 may fill the gaps between dummy gates 108 and other existing devices within the semiconductor substrate 102. The first ILD layer 402 may include: silicon oxide, silicon nitride, silicon oxynitride, carbon-doped silicon oxide or any other suitable dielectric material.

Referring now to FIG. 5, a top portion of the first ILD layer 402 shown in FIG. 4 may be removed by a CMP process until a top of the CMP stop layer 302 is reached. A portion of the first ILD layer 502 may remain in structure 500 filling the space between the dummy gates 108 and other existing devices within the semiconductor substrate 102.

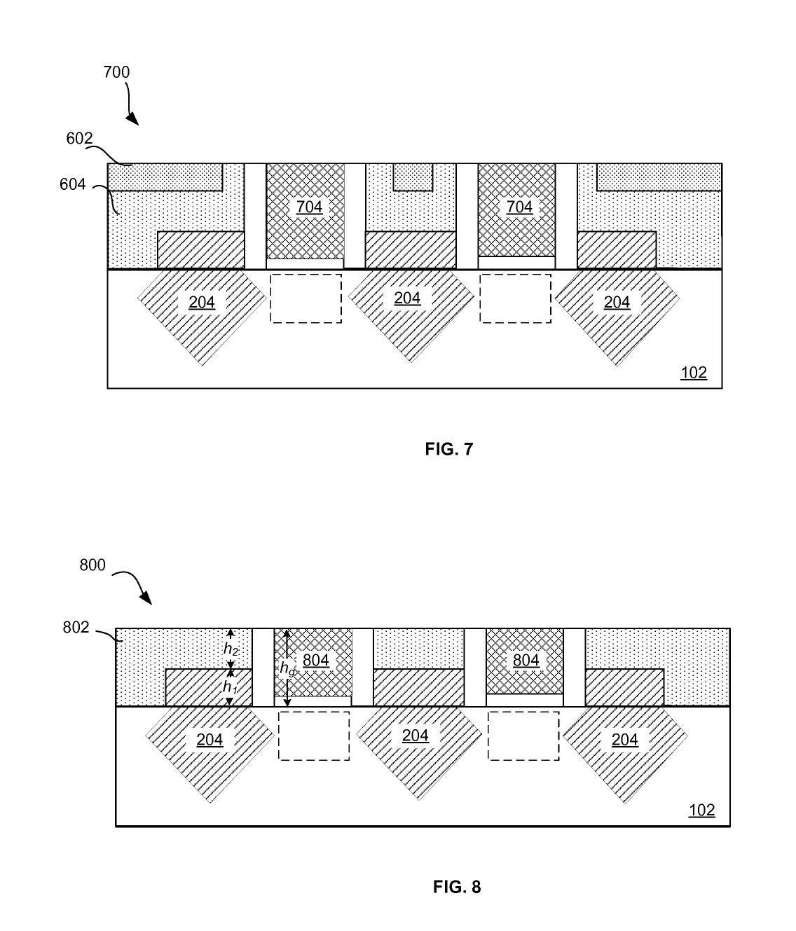

Referring now to FIG. 6, a reactive ion etching technique may be used to remove the CMP stop layer 302 from the top of the dummy gates 108 (FIG. 5). A portion of the CMP stop layer 604 may remain above the RSD regions 204 and along the sidewalls of the spacers 110. Additionally, the portion of the first ILD layer 502 on top of the CMP stop layer 302 (FIG. 5) may be partially removed during etching of the CMP stop layer 302. A second portion of the first ILD layer (602) may remain in some areas above the portion of the CMP stop layer 604 and between the dummy gates 108. Next, another CMP process may be performed to remove the hard mask layer 112 (FIG. 5) and expose the dummy gate 108.

Referring now to FIG. 7, the dummy gate 108 shown in FIG. 6 may be removed selective to the spacers 110 by any suitable etching technique known in the art. For example, the dummy gate 108 may be selectively etched by means of a wet etch process. Etching of the dummy gate 108 may create a recess between adjacent spacers 110. Such recess may be subsequently filled with a conductive material and form a metal gate 704. The metal gate 704 may be formed by any suitable deposition process including, but not limited to CVD, PECVD, HDCVD, PVD, plating, sputtering, evaporation, and chemical solution deposition.

For example, the metal gate 704 in a p-FET device may include a p-type metal including titanium nitride (TiN), tungsten nitride (WN), tantalum nitride (TaN) or other suitable materials.

For example, the metal gate 704 in an n-FET device may include an n-type metal including titanium aluminide (TiAl), titanium aluminum nitride (TiAlN) or other suitable materials.

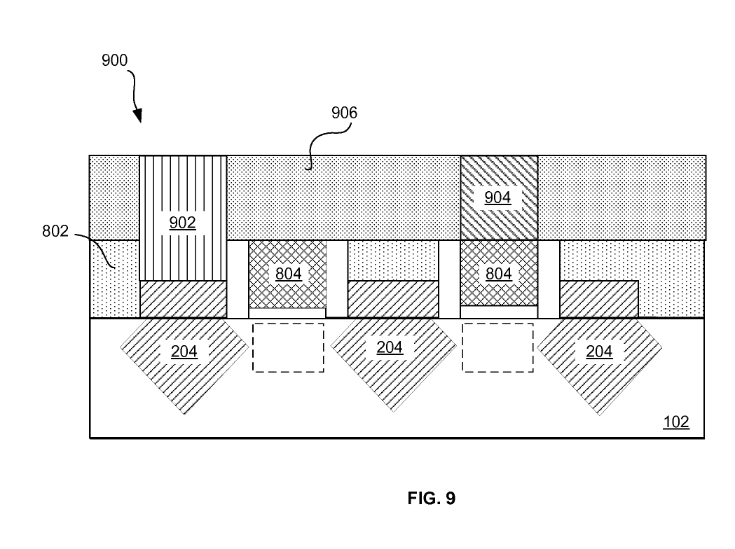

Referring now to FIG. 8, a CMP process may be performed until a top surface of the remaining CMP stop layer 604 (FIG. 7) located above the RSD regions 204 is reached. In doing so the height of the metal gate 704 may be reduced and result in a metal gate 804. The CMP process may result in multiple polished metal gates 804 of substantially uniform height within the semiconductor structure 800. The height (h_{g}) of the polished metal gates 804 may be substantially similar to the thickness (h₁) of the RSD region 204 above the semiconductor substrate 102 plus the thickness (h₂) of the remaining CMP stop layer 802 above the RSD region 204, as illustrated in the figure.

The aforementioned steps may provide a method for controlling combined poly open and replacement metal chemical mechanical polish (CMP) during the replacement metal gate (RMG) process. Uncontrolled poly open and replacement metal CMP may result in shorter metal gate height. In severe over polish cases the height of the replacement metal gate may be the same as the raised source-drain region (RSD) epi overfill which may result in problems such as attack of RSD regions, severe silicon gouging, silicide placement near the channel region and increase leakage. The deposition of a CMP stop layer made of a chemical resistant carbon-based material directly on top of the dummy gates and RSD regions of the semiconductor substrate may prevent the CMP process to continue hence avoiding over polish of the metal gates and allowing uniform metal gate height in the semiconductor device.

Referring now to FIG. 9, a second ILD layer 906 may be placed on top of the polished metal gates 804 shown in FIG. 8. The second ILD layer 906 may separate the polished metal gates 804 (FIG. 8) from device wiring levels which may be subsequently formed above. The second ILD layer 906 may be formed by any suitable deposition process such as: CVD, PECVD, HDCVD, PVD, plating, sputtering, evaporation, and chemical solution deposition.

Finally, contacts, for example substrate contacts 902 may be formed in the second ILD layer 906. The formation of contacts may further include the salicidation of the RSD regions 204. The contacts (902, 904) may be patterned by means of a photolithography process. Following the photolithography process, areas of the second ILD layer 906 may be etched to create contact holes and then a metal layer (not shown) may be deposited within the contact holes and over the entire semiconductor substrate by means of any deposition method known in the art including, for example, by CVD, PECVD, HDCVD, PVD, plating, sputtering, evaporation, and chemical solution deposition. In one embodiment of the present disclosure, the metal layer may include a nickel-platinum alloy (NiPt) where the atomic concentration of nickel (Ni) may range from about 70-95%. In another embodiment of the present disclosure, the metal layer may include nickel palladium (NiPd), nickel rhenium (NiRe), titanium (Ti), titanium tantalum (TiTa), titanium niobium (TiNb), or cobalt (Co). Alternatively, other metals commonly employed in salicide processing such as tantalum (Ta), tungsten (W), cobalt (Co), nickel (Ni), platinum (Pt), palladium (Pd), or alloys thereof may be employed.

After the metal layer is formed, the structure 900 may be subjected to a thermal annealing process, using conventional processes such as, but not limited to, rapid thermal annealing (RTA). During the thermal annealing process, the metal layer reacts with the silicon present in the RSD regions 204 to form a metal silicide. After the annealing process, an etching process may be carried out to remove substantially all un-reacted metal or metal alloy of the remaining portion of the metal layer. The etching process may include a wet etching method.

Next, gate contacts 904 may be patterned and formed. The process of patterning and formation of gate contacts may include a succession of techniques that may include photolithography and photomasking, wet or dry etching and metal deposition.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

1. A method of manufacturing a semiconductor structure, comprising:
forming a chemical mechanical polish (CMP) stop layer, conformally, over a dummy gate, a raised source-drain region of a semiconductor substrate, and a top surface of the semiconductor substrate, wherein a first top surface of the CMP stop layer is located directly above the dummy gate and a second top surface of the CMP stop layer is located below the first top surface of the CMP stop layer directly above the raised source-drain region;
replacing the dummy gate with a metal gate; and
polishing the metal gate until the second top surface of the CMP stop layer is substantially flush with a top surface of the metal gate.

2. The method of claim 1, wherein the CMP stop layer comprises a dense carbon-based film.

3. The method of claim 1, wherein the CMP stop layer comprises silicon carbon nitride.

4. The method of claim 1, wherein the CMP stop layer comprises a thickness ranging from about 5 nm to about 25 nm.

5. The method of claim 1, further comprising:
etching a portion of the CMP stop layer located above the dummy gate to expose the dummy gate.

6. The method of claim 1, further comprising:
forming raised source drain regions adjacent to the dummy gate.

7. A method, comprising:
forming a raised source drain region in a semiconductor substrate adjacent to a dummy gate;
forming a chemical mechanical polish (CMP) stop layer over a dummy gate above the raised source drain region of a semiconductor substrate and above a top surface of the semiconductor substrate;
forming a first interlayer dielectric (ILD) layer above the CMP stop layer;
polishing a portion of the first ILD layer until the CMP stop layer located above the dummy gate is exposed, wherein the CMP stop layer impedes the polishing process;
etching a portion of the CMP stop layer located above the dummy gate to expose the dummy gate, wherein a first top surface of the CMP stop layer is substantially flush with a top surface of the dummy gate and a second top surface of the CMP stop layer is located below the first top surface of the CMP stop layer directly above the raised source-drain region;
replacing the dummy gate with a metal gate; and
polishing the metal gate until the second top surface of the CMP stop layer is substantially flush with a top surface of the metal gate.

8. The method of claim 7, wherein the CMP stop layer comprises a dense carbon-based film.

9. The method of claim 7, wherein the CMP stop layer comprises silicon carbon nitride.

10. The method of claim 7, wherein the CMP stop layer comprises a thickness ranging from about 5 nm to about 25 nm.

11. The method of claim 7, wherein forming the raised source drain region comprises epitaxially growing a doped material having compressive or tensile strain properties.

12. The method of claim 7, wherein forming the raised source-drain region further comprises epitaxially growing a silicon-germanium or carbon-doped silicon material including p-type or n-type dopants respectively.

13. The method of claim 7, further comprising:
removing a hard mask layer located between the CMP stop layer and the dummy gate to expose the dummy gate.

14. The method of claim 7, wherein replacing the dummy gate with the metal gate comprises depositing a p-type metal or an n-type metal in a recess formed by the removal of the dummy gate.

15. The method of claim 7, wherein polishing the metal gate until a top of the CMP stop layer is exposed comprises:
using a chemical mechanical polish technique.

16. The method of claim 7, wherein a height of the metal gate is substantially the same as a thickness of the CMP stop layer plus a thickness of a portion of the raised source-drain region extending above the semiconductor substrate, the height of the metal gate is measured from a top surface of the semiconductor substrate up to a top surface of the metal gate, the thickness of the CMP stop layer is measured from a top surface of the raised source drain region up to the second top surface of the CMP stop layer.

17. The method of claim 18, wherein forming the contacts within the second ILD layer comprises patterning and silicidation of substrate contacts and patterning of gate contacts.

18. The method of claim 7, further comprising:
forming a second ILD layer above the structure; and
forming contacts within the second ILD layer, the contacts extending from a top surface of the second ILD layer to the raised source drain region.

19-20. (canceled)

21. The method of claim 1, wherein a height of the metal gate is substantially the same as a thickness of the CMP stop layer plus a thickness of a portion of the raised source-drain region extending above the semiconductor substrate, the height of the metal gate is measured from a top surface of the semiconductor substrate up to a top surface of the metal gate, the thickness of the CMP stop layer is measured from a top surface of the raised source drain region up to the second top surface of the CMP stop layer.
